(19) United States
(12) Patent Application Publication
(10) Pub. No.: US 2026/0309748 A1
(43) Pub. Date: Oct. 8, 2026

(54) CANTILEVER HOLDER STRUCTURE WITH ATTACHED ELECTRICAL COMPONENTS FOR A CANTILEVER-CARD ASSEMBLY AND METHODS OF FORMING THE SAME

(71) Applicant: Taiwan Semiconductor Manufacturing Company Limited, Hsinchu (TW)

(72) Inventors: Po Sheng LIN, Taichung City (TW); Jia Hong LIAO, New Taipei City (TW); Yu-Hsuan CHENG, Hsinchu City (TW); Yan Wei CHANG, New Taipei City (TW); Kai-Yi TANG, New Taipei City (TW)

(21) Appl. No.: 19/170,307

(22) Filed: Apr. 4, 2025

(51) Int. Cl. G01R 1/067; G01R 3/00; G01R 31/26; G01R 31/28

(52) U.S. Cl. CPC G01R 1/06727; G01R 1/0675; G01R 3/00; G01R 31/2601; G01R 31/2886

(57) ABSTRACT

A method of operating a test apparatus comprises: providing a cantilever-card assembly that includes a cantilever holder structure attached to a bottom of a probe card, cantilever probe needles having first end portions embedded within the cantilever holder structure, at least one auxiliary circuit board that is attached to the cantilever holder structure, and electrical components attached to the at least one auxiliary circuit board; positioning a semiconductor wafer including semiconductor devices under the cantilever probe needles; disposing the cantilever probe needles on test pads on the semiconductor wafer; and generating data representing electrical characteristics of the semiconductor devices.

### BACKGROUND

Cantilever-card assemblies are widely used in semiconductor testing due to their ability to achieve fine pitch alignment between probe needles and semiconductor wafers. However, related cantilever probe designs often face challenges in signal integrity (SI) and power integrity (PI), particularly in high-speed testing environments. These issues are primarily caused by the long cantilever needle length and the placement of electrical components, such as resistors and capacitors, far from the wafer. The long electrical transmission paths lead to increased coupling noise and reduced performance, limiting the ability of cantilever-card assemblies to support the demands of modern semiconductor testing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a test apparatus according to an embodiment of the present disclosure.

FIG. 2A is a first vertical cross-sectional view of a first exemplary cantilever-card assembly according to an embodiment of the present disclosure. FIG. 2B is a side view of the first exemplary cantilever-card assembly along the horizontal direction B in FIG. 2A. The vertical plane A-A′ in FIG. 2B is the cut plane of the first vertical cross-sectional view of FIG. 2A. FIG. 2C is a second vertical cross-sectional view of the first exemplary cantilever-card assembly along the vertical plane C-C′ in FIG. 2B.

FIG. 3A is a first vertical cross-sectional view of a second exemplary cantilever-card assembly according to an embodiment of the present disclosure. FIG. 3B is a side view of the second exemplary cantilever-card assembly along the horizontal direction B in FIG. 3A. The vertical plane A-A′ in FIG. 3B is the cut plane of the first vertical cross-sectional view of FIG. 3A. FIG. 3C is a second vertical cross-sectional view of the second exemplary cantilever-card assembly along the vertical plane C-C′ in FIG. 3B.

FIG. 4A is a first vertical cross-sectional view of a third exemplary cantilever-card assembly according to an embodiment of the present disclosure. FIG. 4B is a side view of the third exemplary cantilever-card assembly along the horizontal direction B in FIG. 4A. The vertical plane A-A′ in FIG. 4B is the cut plane of the first vertical cross-sectional view of FIG. 4A. FIG. 4C is a second vertical cross-sectional view of the third exemplary cantilever-card assembly along the vertical plane C-C′ in FIG. 4B. FIG. 4D is a third vertical cross-sectional view of the third exemplary cantilever-card assembly along the vertical plane D-D′ in FIG. 4B. FIG. 4E is a fourth vertical cross-sectional view of the third exemplary cantilever-card assembly along the vertical plane E-E′ in FIG. 4B.

FIG. 5 is a see-through perspective view of a cantilever-card assembly in which cantilever probe needles and connection wires are illustrated as if a probe card was transparent according to an embodiment of the present disclosure.

FIG. 6A is a plan view with a magnified portion of a wafer including semiconductor dies and test pads according to an embodiment of the present disclosure.

FIG. 6B is a vertical cross-sectional view of a wafer including semiconductor dies and test pads according to an embodiment of the present disclosure.

FIG. 7 is a vertical cross-sectional view of a portion of the test apparatus of FIG. 1 during testing of a semiconductor die using test pads on the wafer according to an embodiment of the present disclosure.

FIG. 8 is a first flowchart that illustrates the general processing steps for operating a test apparatus according to an aspect of the present disclosure.

FIG. 9 is a second flowchart that illustrates the general processing steps for manufacturing a test apparatus according to an aspect of the present disclosure.

### DETAILED DESCRIPTION

The following disclosure provides many different embodiments, or examples, for implementing various features of the provided subject matter. Specific examples of components and arrangements are described below to clarify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. A first physical element is “embedded” with a second physical element if the entire volume of the first element is located within a hypothetical volume defined by a set of hypothetical surfaces having the least total surface area among all sets of hypothetical surfaces containing the entirety of the outer surfaces of the second element and topologically homeomorphic to a spherical surface. Such a set of hypothetical surfaces covers each opening, if present, in the outer surfaces with a minimum-area surface segment among all possible opening-free surface segments. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

In related probe cards, cantilever probe needles often exceed 4 mm in length, making the cantilever probe needles susceptible to signal degradation and noise coupling. The cantilever probe needles provide electrical paths between the probe card and the device under test. Thus, signals between electrical components (such as capacitors and resistors) on the probe card and the device under test may be delayed during transmission through the cantilever probe needles, and the high-speed performance of the probe card is limited by such signal delay.

Embodiments of the present disclosure incorporate at least one auxiliary circuit board within, or attached to, a cantilever holder structure secured to a bottom of a probe card. A dielectric spacer ring may be interposed between the cantilever holder structure and the probe card, placing the at least one auxiliary circuit board away from the probe card while keeping the at least one auxiliary circuit board in close proximity to the wafer under test. The arrangement shortens electrical paths and stabilizes power delivery. Signal integrity and power integrity are enhanced due to the reduced length of electrical paths.

The lengths of the cantilever probe needles may be reduced by embedding first end portions of the cantilever probe needles within the cantilever holder structure. The middle portions of the cantilever probe needles extend through the cantilever holder structure. The second end portions of the cantilever probe needles vertically extend downward to make contact with the wafer. Parasitic effects may be minimized by positioning electrical components, such as resistors, capacitors, and inductors, on the at least one auxiliary circuit board in direct contact with, or spaced from, the cantilever holder structure. Noise coupling is reduced by placing the electrical components closer to the wafer.

Solder material portions may be used to attach connection wires that link the electrical components on the at least one auxiliary circuit board to conductive structures on the probe card. A subset of cantilever probe needles may be connected to the probe card via a respective electrical component, and a second subset of cantilever probe needles may be connected to the probe card without any intermediate electrical component. The at least one auxiliary circuit board may be a flexible printed circuit with a lower Young's modulus than the probe card or a satellite printed circuit board attached through an adhesive layer to the cantilever holder structure. Shortening the cantilever probe needles mitigates signal loss and parasitic inductance, which improves performance of the probe card for high-frequency applications. Placing electrical components on or within the cantilever holder structure reduces the path length to the semiconductor wafer, stabilizing decoupling and boosting power integrity. The overall cantilever-card assembly structure supports more reliable high-speed testing, resulting in improved data generation for semiconductor devices. Various embodiments of the present disclosure are now described with reference to accompanying drawings.

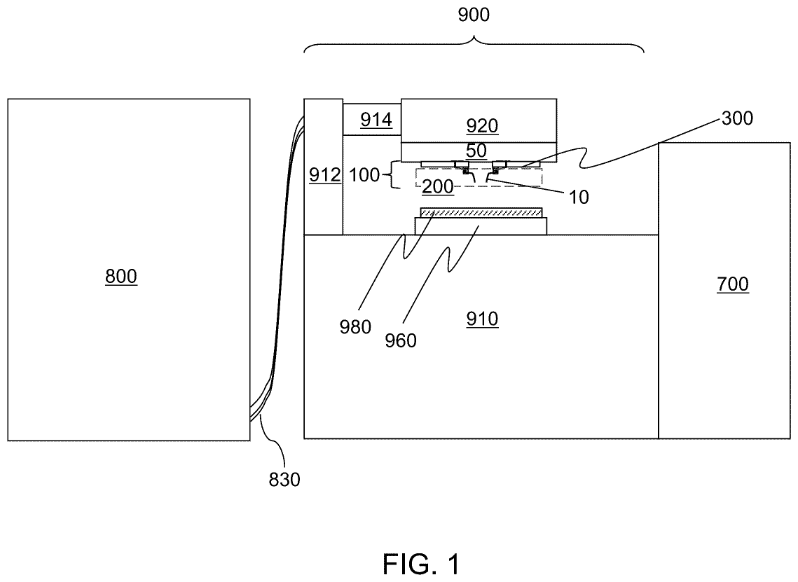

Referring to FIG. 1, an embodiment test apparatus illustrating an aspect of the present disclosure is provided. The embodiment test apparatus may include a tester electronics unit 800 including at least one computer and peripheral devices, a wafer prober 900 in communication with the tester electronics unit 800, for example, via signal and power cables 830, and an optional wafer conveyer unit 700 configured to load and unload a device under test (DUT) 980 to be tested on the wafer prober 900. The wafer prober 900 may include a wafer chuck 960 configured to hold a device under test (DUT) 980 thereupon, a prober frame 910 containing a stage drive unit configured to laterally drive the wafer chuck 960, a tester head 920 that overlies the wafer chuck 960, and tester head support structures (912, 914) configured to structurally support, and to provide movement to, the tester head 920.

The probe card 300 may comprise a printed circuit board (PCB) containing a plastic substrate and printed circuits thereupon. The probe card 300 is commonly referred to as a main board. A cantilever-holder assembly 200 may be attached to the bottom of the probe card 300. As will be described in detail below, the cantilever-holder assembly 200 comprises cantilever probe needles having first end portions embedded within a cantilever holder structure, at least one auxiliary circuit board that is attached to the cantilever holder structure, and electrical components attached to the at least one auxiliary circuit board. The combination of the cantilever-holder assembly 200 and the probe card 300 constitutes a cantilever-card assembly 100.

A probe support assembly 50 may be attached to the top of the probe card 300. The probe support assembly 50 may comprise a stiffener, which may be attached to the backside of the probe card 300 to reduce structural deformation of the probe card 300 due to thermal and/or mechanical stress during use of the probe card 300. The probe support assembly 50 may be subsequently attached to the bottom of the tester head 920 using a suitable array of contact structures such as an array of spring-type contact pins.

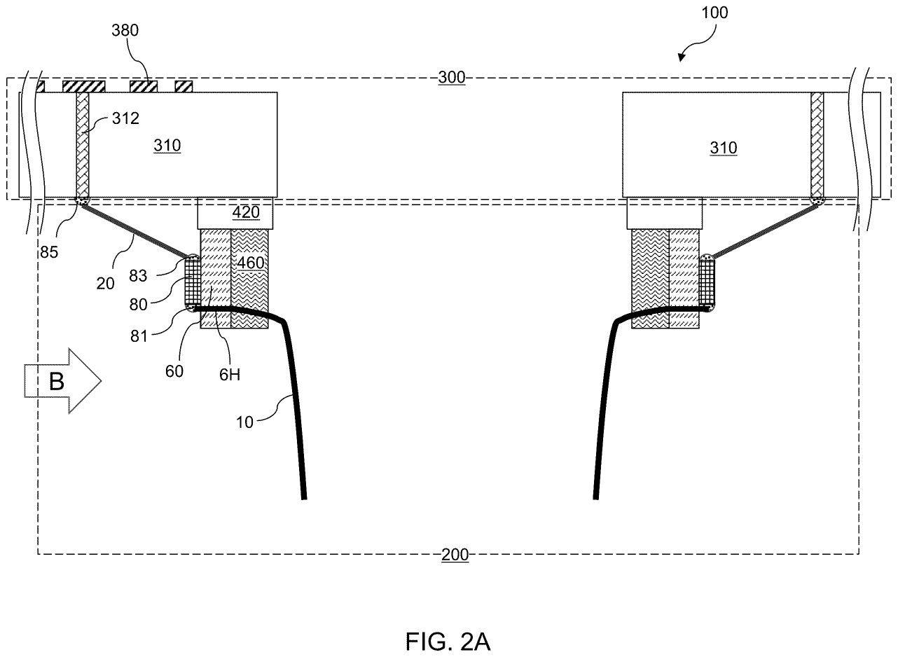

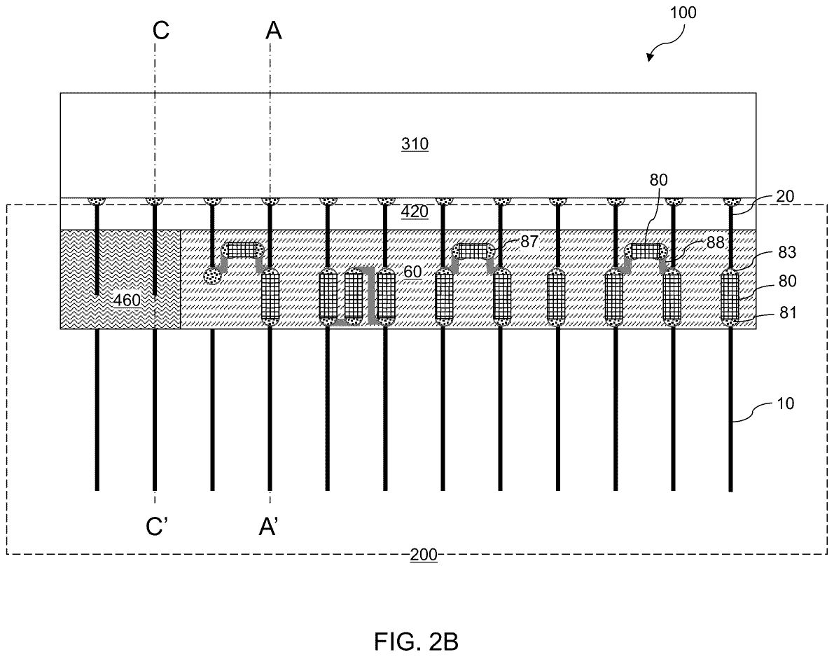

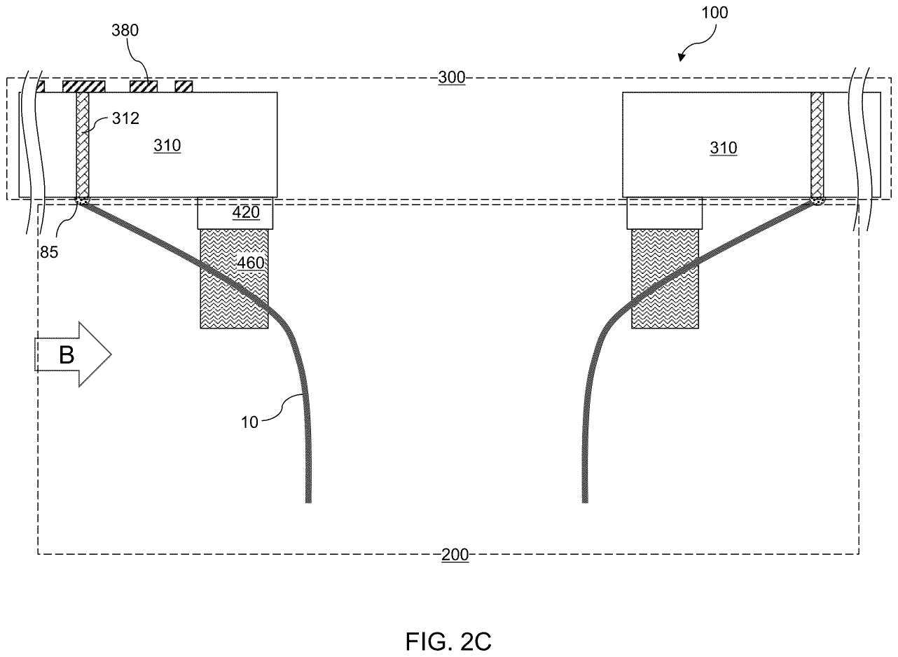

FIG. 2A is a first vertical cross-sectional view of a first exemplary cantilever-card assembly 100 according to an embodiment of the present disclosure. FIG. 2B is a side view of the first exemplary cantilever-card assembly 100 along the horizontal direction B in FIG. 2A. The vertical plane A-A′ in FIG. 2B is the cut plane of the first vertical cross-sectional view of FIG. 2A. FIG. 2C is a second vertical cross-sectional view of the first exemplary cantilever-card assembly 100 along the vertical plane C-C′ in FIG. 2B.

Referring to FIG. 2A-2C, the first exemplary cantilever-card assembly 100 may be formed by providing at least one auxiliary circuit board 60. The at least one auxiliary circuit board 60 may be a single auxiliary circuit board 60, or may be a plurality of auxiliary circuit boards 60. In one embodiment, the at least one auxiliary circuit board 60 comprises a flexible printed circuit comprising a dielectric substrate having a lower Young's modulus than a substrate material of the probe card 300 and having a lesser thickness than the probe card 300. In one embodiment, the at least one auxiliary circuit board 60 may comprise at least one flexible printed circuit (FPC). While a typical printed circuit board is rigid and has limited conformability, a flexible printed circuit includes a thin, pliable substrate, and thus, may be bent or folded to fit compact or irregularly shaped spaces. In one embodiment, the substrate of the printed circuit board may comprise glass-reinforced epoxy laminate, and the at least one auxiliary circuit board 60 may comprise polyimide (PI), polyester (PET), or polytetrafluoroethylene (PTFE).

Electrical components 80 may be soldered onto the at least one auxiliary circuit board 60. The electrical components 80 comprise capacitors, resistors, inductors, and/or other passive electrical components known in the art. Each electrical component 80 may be attached to a respective auxiliary circuit board by glue or an alternative adhesive material. Additionally or alternatively, the electrical components may be soldered onto metallic structures, such as conductive pads or traces, that are located on the at least one auxiliary circuit board 60.

First cantilever probe needles 10 may be provided. Each of the first cantilever probe needles 10 may be configured to extend from a first end of a respective electrical component 80 to a contact position of the respective first cantilever probe needle 10, i.e., the position at which a tip of the respective first cantilever probe needle 10 makes a physical contact with a test pad on a device under test. The at least one auxiliary circuit board 60 may comprise through-holes 6H, each of which may be configured to allow passing of an end portion of a first cantilever probe needle 10. A first end of each of the cantilever probe needles 10 may pass through a respective through-hole 6H in a respective auxiliary circuit board 60, and may be attached to the first end of a respective electrical component 80 by soldering. For example, the first end of each of the cantilever probe needles 10 may be attached to the first end of a respective electrical component 80 through a first solder material portion 81. The length of the cantilever probe needles 10 that are attached to a respective one of the electrical components may be in a range from 30 micron to 100 micron, and preferably in a range from 30 micron to 60 micron. The reduction in the length of the cantilever probe needles 10 between an electrical component 80 and a contact point with a device under test reduces coupled noise and improves signal and power integrity through shortening of high-speed loopback routings.

The at least one auxiliary circuit board 60 and the attached cantilever probe needles 10 may be aligned to a test configuration, i.e., a configuration in which the cantilever probe needles 10 contact a device under test during subsequent testing. In some embodiments, additional cantilever probe needles 10 configured to extend directly from the probe card 300 to the device under test may be used. In this embodiment, the additional cantilever probe needles 10 are also aligned to the test configuration.

A temporary mold (not shown) may be disposed around the combination of the at least one auxiliary circuit board 60 and the attached cantilever probe needles 10, and a molding compound material, such as epoxy resin or polyurethane, may be applied around the at least one auxiliary circuit board 60 to form a cantilever holder structure 460. First end portions of the cantilever probe needles 10 become embedded within the cantilever holder structure 460, i.e., are surrounded by the cantilever holder structure 460 in a manner that provides immersion therein. The at least one auxiliary circuit board 60 may be embedded within the cantilever holder structure 460. The electrical components 80 are attached to the at least one auxiliary circuit board 60. Further, middle portions of the additional cantilever probe needles 10 become embedded within the cantilever holder structure 460. In one embodiment, the cantilever holder structure 460 may have a shape of a rounded rectangular ring. In this embodiment, the cantilever holder structures 460 may be referred to as a cantilever holder ring.

In one embodiment, the cantilever holder structure 460 may be frame-shaped, i.e., may have the shape of a frame having an opening therein. The first ends portions of each cantilever probe needle 10 may extend through the cantilever holder structure 460, and may be attached to a respective one of the electrical components 80 on the out-side of a respective outer sidewall of the cantilever holder structure 460. In one embodiment, the dielectric material of the cantilever holder structure 460 may be molded such that each auxiliary circuit board 60 comprises a respective planar surface in direct contact with the cantilever holder structure 460. In one embodiment, each of the at least one auxiliary circuit board 60 may comprise a first planar surface on which a set of electrical components 80 are disposed, and a second planar sidewall in direct contact with the cantilever holder structure 460. In one embodiment, the first planar surface may not directly contact the cantilever holder structure 460, and the entirety of the second planar surface may be in contact with the cantilever holder structure 460. In one embodiment, the at least one auxiliary circuit board 60 may have a lesser vertical extent than the cantilever holder structure 460. In one embodiment, the top surface(s) of the at least one auxiliary circuit board 60 may be coplanar with the top surface of the cantilever holder structure 460.

A dielectric spacer ring 420 may be provided. The dielectric spacer ring 420 may have a uniform vertical thickness, and may have substantially the same horizontal cross-sectional shape as the assembly of the cantilever holder structure 460 and the at least one auxiliary circuit board 60. The vertical thickness of the dielectric spacer ring 420 may be in a range from 5 microns to 50 microns, although lesser or greater thicknesses may also be used. The dielectric spacer ring 420 may be attached to the cantilever holder structure 460 using a first adhesive material layer (not illustrated).

The cantilever holder structure 460 is attached to the probe card 300. In embodiments in which a dielectric spacer ring 420 is used, the dielectric spacer ring 420 may be interposed between the cantilever holder structure 460 and the probe card 300 while attaching the cantilever holder structure 460 to the probe card 300. In this embodiment, the at least one auxiliary circuit board 60 is vertically spaced from the probe card 300 by the dielectric spacer ring 420.

The probe card 300 comprises electrically conductive structures (312, 380), which may comprise traces 380 and through-board via structures 312 formed in dielectric substrate 310. Connection wires 20 may be used to provide electrical connections between second ends of the electrical components 80 and the electrically conductive structures (312, 380) on the probe card 300. Each connection wire 20 may be bonded to a respective one of the electrical components 80 through a respective second solder material portion 83, and may be bonded to a respective one of the electrically conductive structures (312, 380) through a respective third solder material portion 85. Generally, second ends of the electrical components 80 may be electrically connected to electrically conductive structures (312, 380) in the probe card 300 using the connection wires 20. Further, the additional cantilever probe needles 20 that are configured to be directly bonded to the probe card 300 without any intermediate electrical component may be bonded to a respective one of the electrically conductive structures (312, 380) through a respective additional third solder material portion 85.

Optionally, the at least one auxiliary circuit board 60 may comprise auxiliary board traces 87 configured to provide electrical connections among the cantilever probe needles 10 and the additional cantilever probe needles 20 on the surface(s) of the at least one auxiliary circuit board 60. Further, additional electrical components 80 may be mounted to the at least one auxiliary circuit board 60 employing fourth solder material portions 87. In one embodiment, the fourth solder material portions 87 may provide solder bonding between electrical nodes of the additional electrical components 80 and a respective one of the auxiliary board traces 87. In some embodiments, a subset of the additional electrical components 80 may provide direct electrical conductive paths between a respective pair of cantilever probe needles 10, between a respective pair of additional cantilever probe needles 20, and/or between a respective pair of a cantilever probe needle 10 and an additional cantilever probe needle 20 over the surface(s) of the at least one auxiliary circuit board 60.

A cantilever-card assembly 100 may be provided, which comprises a cantilever holder structure 460 attached to a bottom of a probe card 300, cantilever probe needles 10 having first end portions embedded within the cantilever holder structure 460, at least one auxiliary circuit board 60 that is attached to the cantilever holder structure 460, and electrical components 80 attached to the at least one auxiliary circuit board 60. In one embodiment, the cantilever-card assembly 100 is provided in a configuration in which each auxiliary circuit board 60 comprises a respective planar surface in direct contact with the cantilever holder structure 460. The planar surface may be parallel to another planar surface to which electrical components 80 are attached. In one embodiment, the cantilever-card assembly 100 is provided in a configuration in which the at least one auxiliary circuit board 60 is vertically spaced from the probe card 300 by a dielectric spacer ring 420 that overlies the cantilever holder structure 460. In one embodiment, the at least one auxiliary circuit board 60 is not in direct contact with the probe card 300.

In one embodiment, the at least one auxiliary circuit board 60 comprises a flexible printed circuit comprising a dielectric substrate having a lower Young's modulus than a substrate material of the probe card 300 and having a lesser thickness than the probe card 300. In one embodiment, the cantilever-card assembly 100 is provided in a configuration in which the cantilever-card assembly 100 comprises solder material portions (81, 83) attached to the electrical components 80, and a subset of the cantilever probe needles 10 is bonded to a first subset of the solder material portions (81, 83, 85) (such as the first solder material portions 81). In one embodiment, the at least one auxiliary circuit board 60 is in direct contact with a dielectric molding material of the cantilever holder structure 460; and the first end portions of the cantilever probe needles 10 extend through the cantilever holder structure 460.

The lengthwise direction of each auxiliary circuit board 60 may be parallel to, or may be perpendicular to, the direction along which contact points of an adjacent set of cantilever probe needles 10 are arranged. The contact points refer to points at which the cantilever probe needles 10 contact the device under test. The first exemplary cantilever-card assembly 100 has a configuration in which the lengthwise direction of each auxiliary circuit board 60 is parallel to the direction along which contact points of an adjacent set of cantilever probe needles 10 are arranged. Further, each auxiliary circuit board 60 may be embedded within the cantilever holder structure 460 such that edge surfaces of the auxiliary circuit board 60 are in direct contact with the molding material of the cantilever holder structure 460.

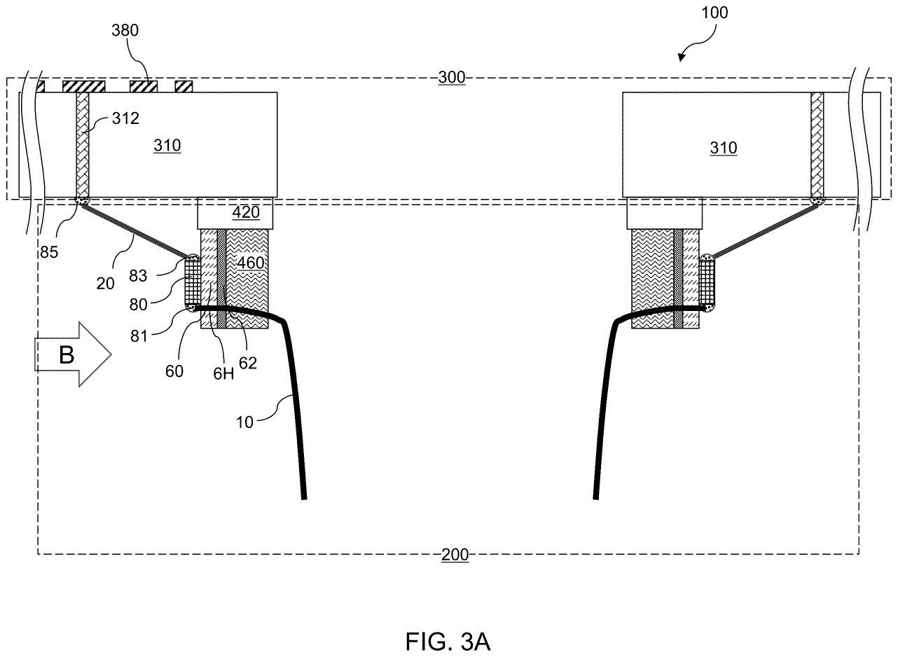

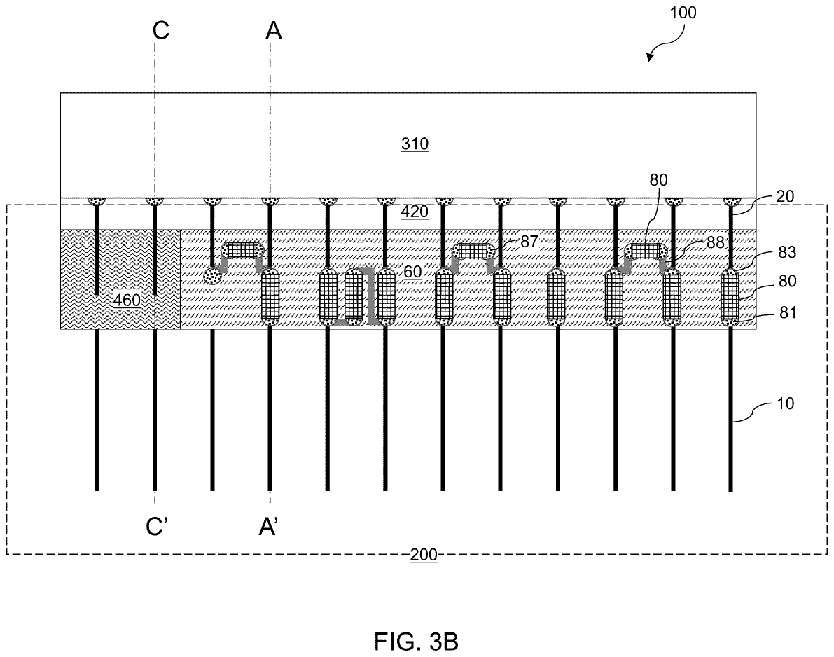

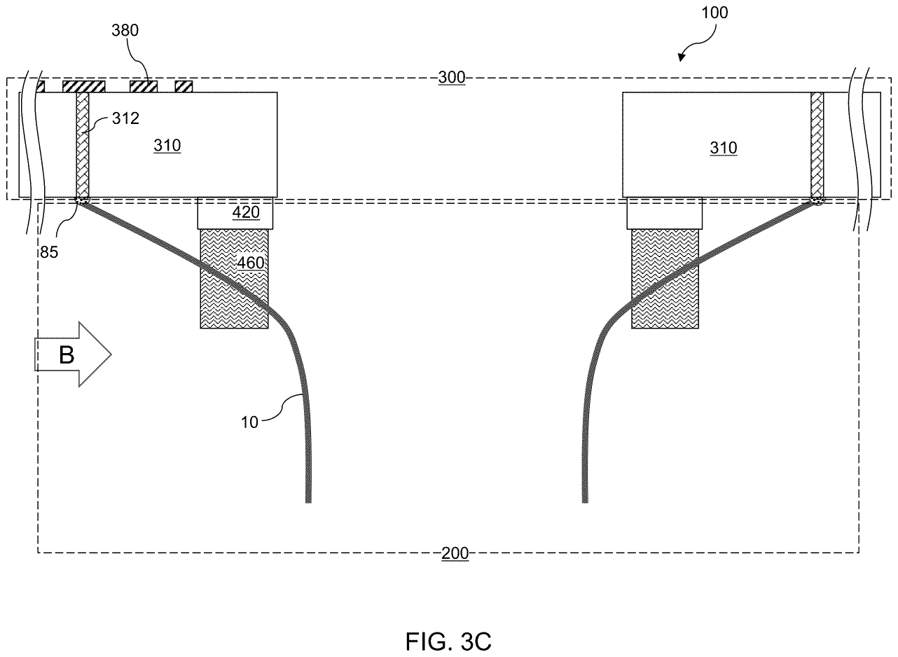

FIG. 3A is a first vertical cross-sectional view of a second exemplary cantilever-card assembly 100 according to an embodiment of the present disclosure. FIG. 3B is a side view of the second exemplary cantilever-card assembly 100 along the horizontal direction B in FIG. 3A. The vertical plane A-A′ in FIG. 3B is the cut plane of the first vertical cross-sectional view of FIG. 3A. FIG. 3C is a second vertical cross-sectional view of the second exemplary cantilever-card assembly 100 along the vertical plane C-C′ in FIG. 3B.

Referring to FIG. 3A-3C, the second exemplary cantilever-card assembly 100 may be derived from the first exemplary cantilever-card assembly 100 illustrated in FIG. 2A-2C by forming the cantilever holder structure 460 such that the cantilever holder structure 460 does not embed any auxiliary circuit board 60. In the second exemplary cantilever-card assembly 100, the at least one auxiliary circuit board 60 comprises a satellite printed circuit board that is attached to the cantilever holder structure 460 through an adhesive layer 62 and laterally spaced from the probe card 300. The at least one auxiliary circuit board 60 may comprise through-holes 6H, each of which may be configured to allow passing of an end portion of a first cantilever probe needle 10. The cantilever probe needles 10 may be affixed to the cantilever holder structure 460 by first aligning the cantilever probe needles in their respective contact positions, and by subsequently forming the cantilever holder structure 460 employing a suitable temporary mold structure. A first end of each of the cantilever probe needles 10 may protrude out of a respective outer vertical sidewall of the cantilever holder structure 460.

An adhesive layer 62 is applied to the vertical sidewalls of the cantilever holder structure 460. The at least one auxiliary circuit board 60 comprises through-holes 6H at locations corresponding to the outward protruding portions of the cantilever probe needles 10. The through-holes 6H of the at least one auxiliary circuit board 60 are aligned to the protruding first end portions of the cantilever probe needles 10, and the at least one auxiliary circuit board 60 is attached to the adhesive layer 62. The tips of the first end portions of the cantilever probe needles 10 are subsequently attached to the first end of a respective electrical component 80 by soldering. In this embodiment, the cantilever holder structure 460 may be formed adjacent to the at least one auxiliary circuit board 60 such that each of the cantilever probe needles 10 comprises a respective portion that is embedded within, and extends through, the cantilever holder structure 460 and a respective auxiliary circuit board 60. The at least one auxiliary circuit board 60 is not in direct contact with the cantilever holder structure 460. The second exem-plary cantilever-card assembly 100 has a configuration in which the lengthwise direction of each auxiliary circuit board 60 is parallel to the direction along which contact points of an adjacent set of cantilever probe needles 10 are arranged.

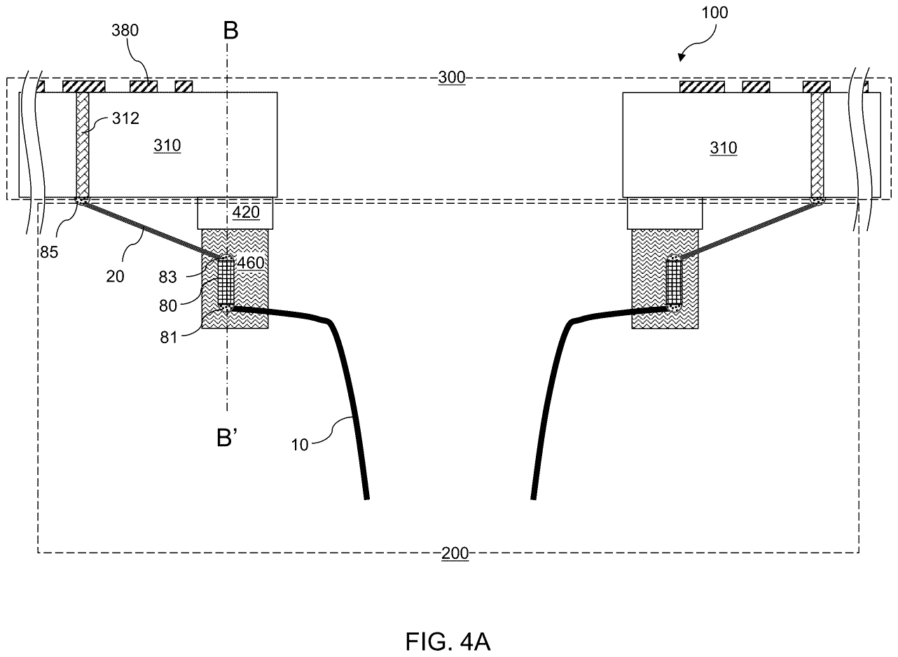

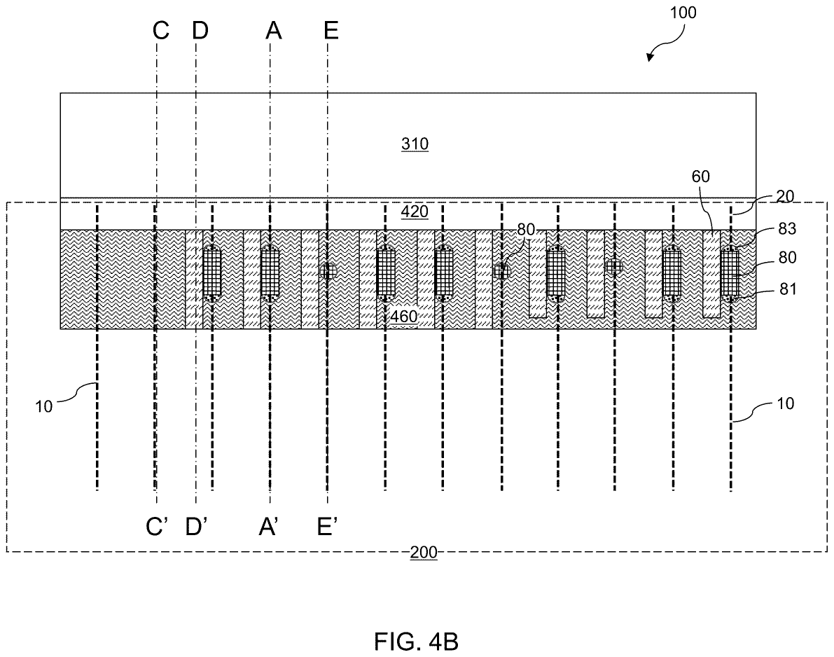

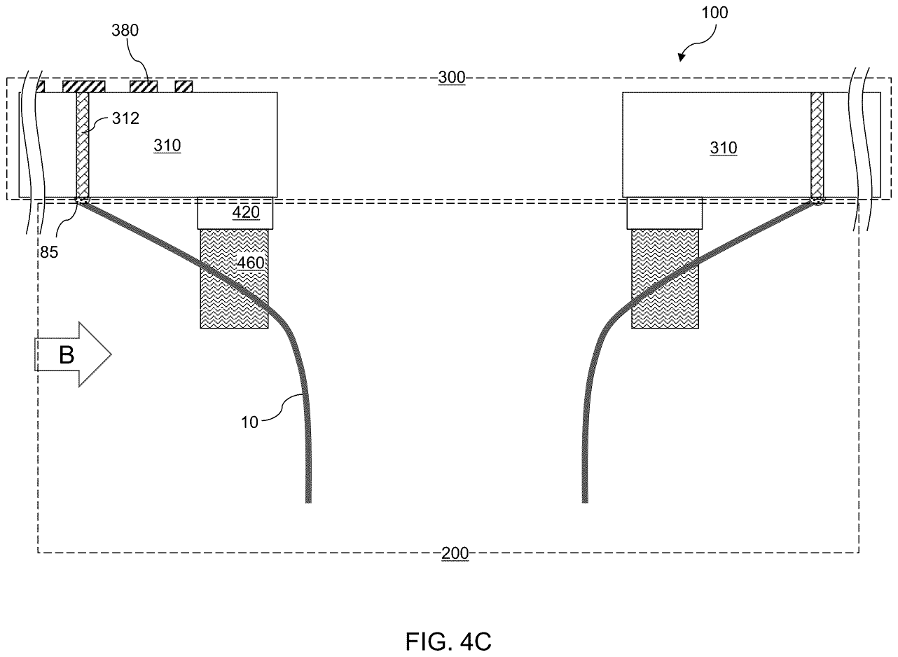

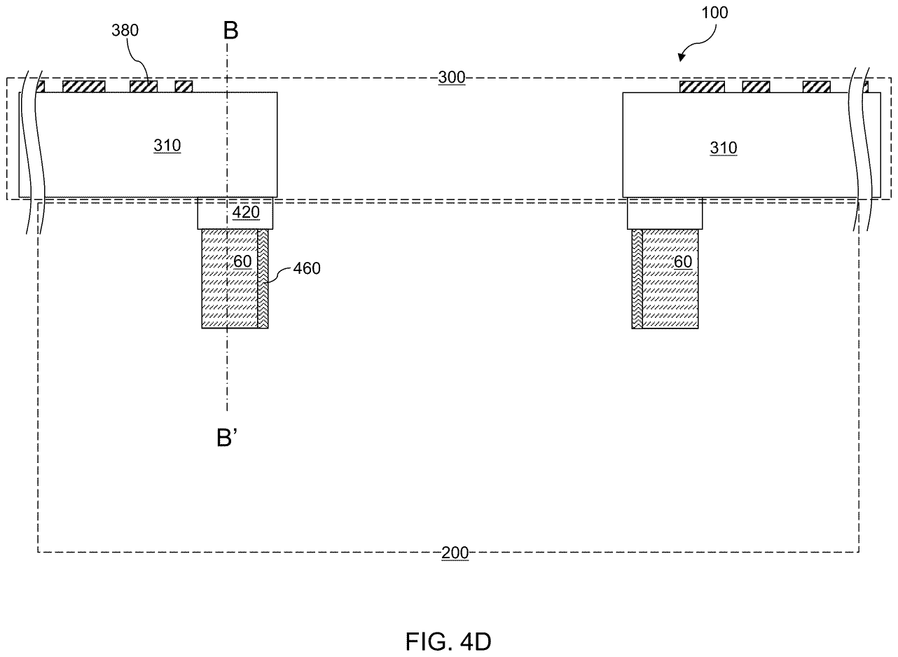

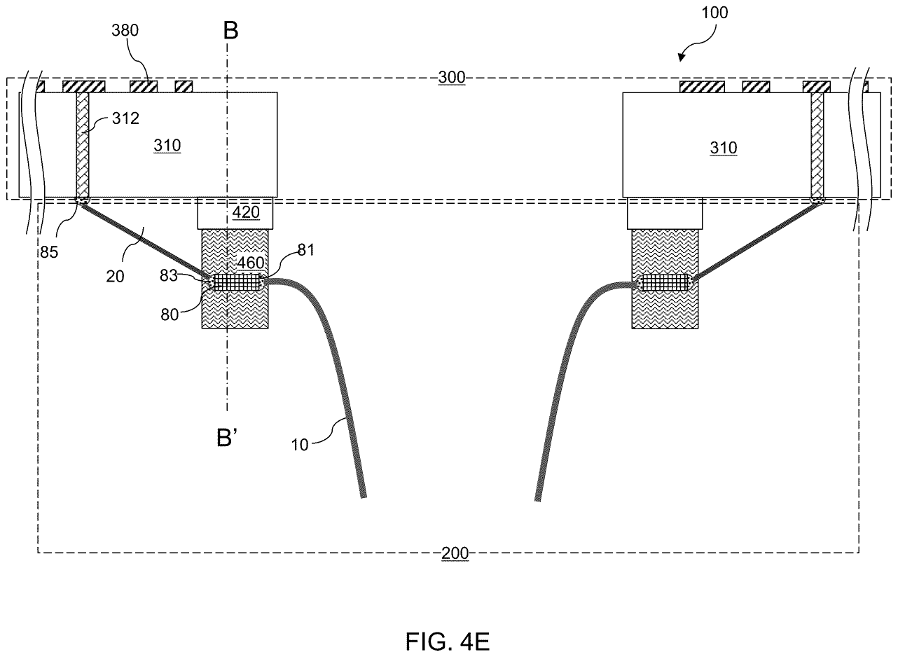

FIG. 4A is a first vertical cross-sectional view of a third exemplary cantilever-card assembly 100 according to an embodiment of the present disclosure. FIG. 4B is a side view of the third exemplary cantilever-card assembly 100 along the horizontal direction B in FIG. 4A. The vertical plane A-A′ in FIG. 4B is the cut plane of the first vertical cross-sectional view of FIG. 4A. FIG. 4C is a second vertical cross-sectional view of the third exemplary cantilever-card assembly 100 along the vertical plane C-C′ in FIG. 4B. FIG. 4D is a third vertical cross-sectional view of the third exemplary cantilever-card assembly 100 along the vertical plane D-D′ in FIG. 4B. FIG. 4E is a fourth vertical cross-sectional view of the third exemplary cantilever-card assembly 100 along the vertical plane E-E′ in FIG. 4B.

Referring to FIG. 4A-4E, the third exemplary cantilever-card assembly 100 may be derived from the first exemplary cantilever-card assembly 100 illustrated in FIG. 2A-2C by forming the cantilever holder structure 460 by using a plurality of auxiliary circuit boards 60, and by aligning the auxiliary circuit boards 60 such that the lengthwise direction of each auxiliary circuit board 60 is perpendicular to the direction along which contact points of an adjacent set of cantilever probe needles 10 are arranged. The plurality of auxiliary circuit boards 60 are embedded within the cantilever holder structure 460. Each of the auxiliary circuit boards 60 may comprise a respective flexible circuit board that is thinner than the probe card 300. The cantilever holder structure 460 may be formed such that each of the cantilever probe needles 10 comprises a respective portion that is embedded within, and extends through, the cantilever holder structure 460. Each auxiliary circuit board 60 is in direct contact with the cantilever holder structure 460. FIG. 4A-4E illustrate examples in which the electrical components 80 are arranged along horizontal directions or along vertical directions. Generally, the electrical components 80 may be oriented in any orientation over the surface of a respective one of the auxiliary circuit boards 60.

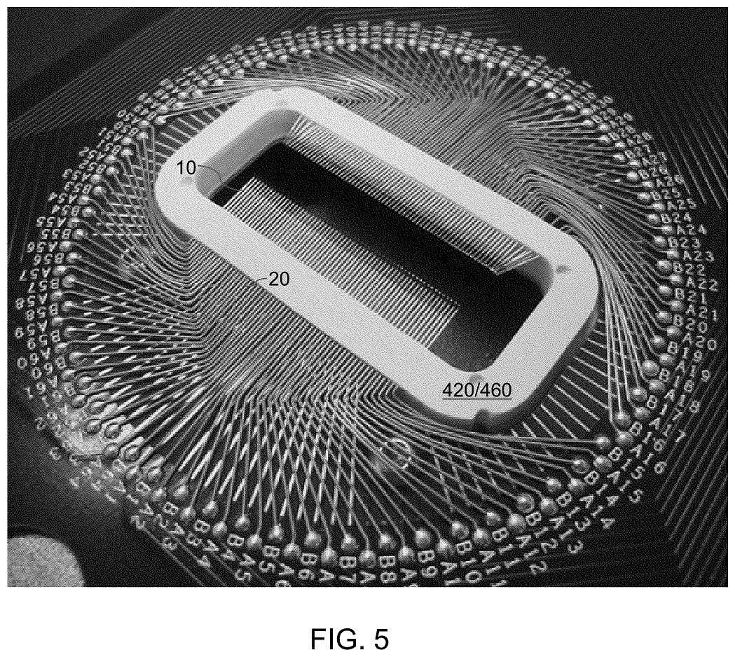

FIG. 5 is a see-through perspective view of a cantilever-card assembly 100 in which cantilever probe needles 10 and connection wires 20 are illustrated as if a probe card 300 was transparent according to an embodiment of the present disclosure.

Referring collectively to FIG. 1-5 and according to various embodiments of the present disclosure, a test apparatus comprising a cantilever-card assembly 100 is provided. The cantilever-card assembly 100 comprises: a probe card 300; a cantilever holder structure 460 attached to a bottom of the probe card 300; cantilever probe needles 10 having first end portions embedded within the cantilever holder structure 460 and having second end portions vertically extending downward; at least one auxiliary circuit board 60 that is attached to the cantilever holder structure 460; and electrical components 80 attached to the at least one auxiliary circuit board 60.

In one embodiment, the at least one auxiliary circuit board 60 is vertically spaced from the probe card 300 by a dielectric spacer ring 420 that overlies the cantilever holder structure 460. In one embodiment, the cantilever-card assembly 100 comprises solder material portions attached to the electrical components 80; and a subset of the cantilever probe needles 10 is bonded to a first subset of the solder material portions (81, 83, 85).

In one embodiment, the at least one auxiliary circuit board 60 comprises a flexible printed circuit comprising a dielectric substrate having a lower Young's modulus than a substrate material of the probe card 300 and having a lesser thickness than the probe card 300 as described with reference to the first exemplary cantilever-card assembly 100 and the third exemplary cantilever-card assembly 100. In one embodiment, the at least one auxiliary circuit board 60 comprises a satellite printed circuit board that is attached to the cantilever holder structure 460 through an adhesive layer 62 and vertically spaced from the probe card 300 as described with reference to the second exem-plary cantilever-card assembly 100.

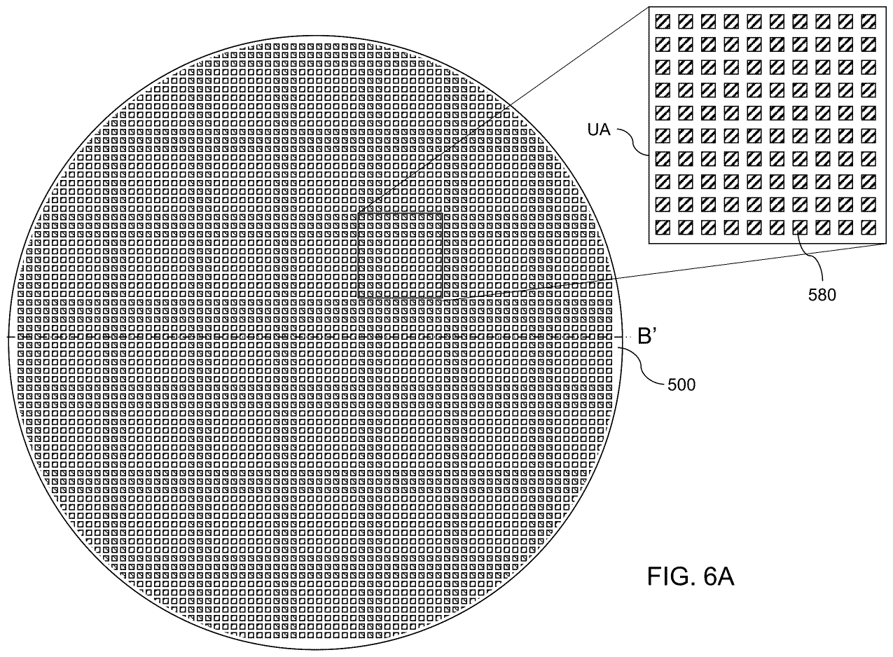

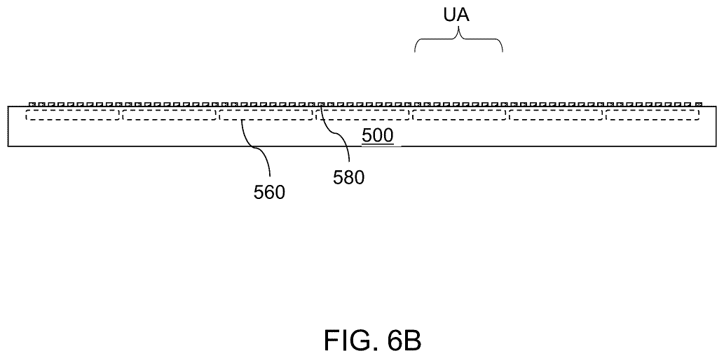

Referring to FIGS. 6A and 6B, a semiconductor wafer 500 including a two-dimensional array of semiconductor dies 560 is illustrated. Each semiconductor die 560 may comprise a respective array of test pads 580. The pattern of a single semiconductor die 560 may be a unit pattern UA, which is repeated within the area of the semiconductor wafer 500 with a two-dimensional periodicity.

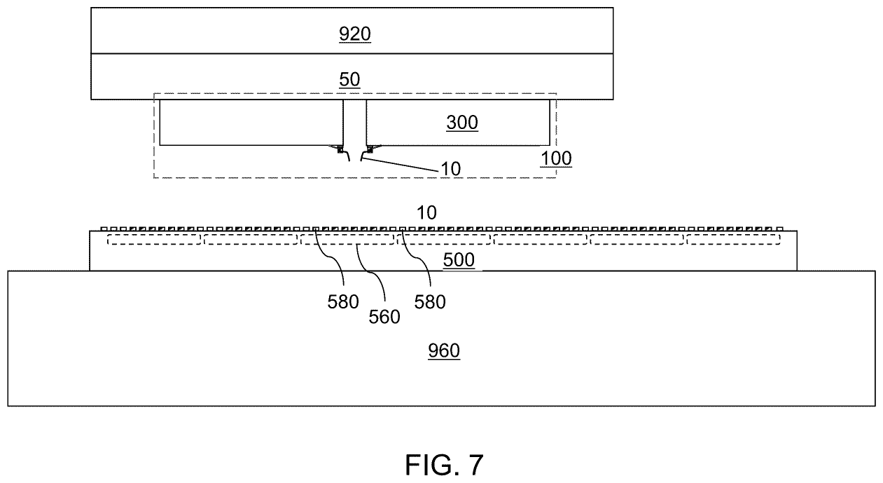

FIG. 7 is a vertical cross-sectional view of a portion of the test apparatus of FIG. 1 during testing of a semiconductor die 560 in the semiconductor wafer 500. Generally, a semiconductor wafer 500 including semiconductor devices may be positioned under the array of cantilever probe needles 10. The array of cantilever probe needles 10 may be aligned to, and may be disposed on, test pads 580 on the semiconductor wafer 500. Data representing electrical characteristics of the semiconductor devices may be generated by running a test program. In this embodiment, the semiconductor dies 560 may be the device under test 980 illustrated in FIG. 1

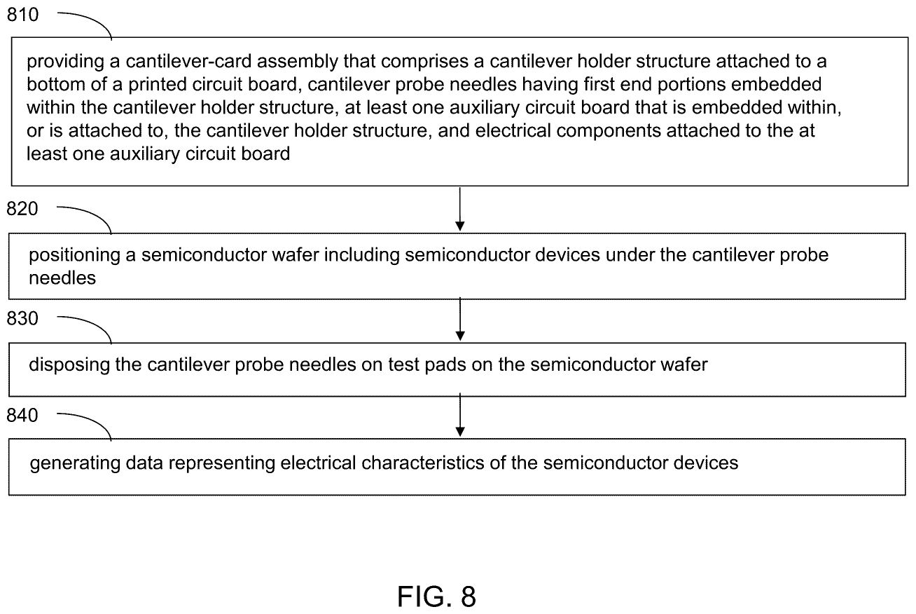

Referring to FIG. 8, a first flowchart illustrates the general processing steps for operating a test apparatus according to an aspect of the present disclosure.

Referring to step 810 and FIG. 1-5, a cantilever-card assembly 100 is provided, which comprises a cantilever holder structure 460 attached to a bottom of a probe card 300, cantilever probe needles 10 having first end portions embedded within the cantilever holder structure 460, at least one auxiliary circuit board 60 that is attached to the cantilever holder structure 460, and electrical components 80 attached to the at least one auxiliary circuit board 60.

Referring to step 820 and FIGS. 6A and 6B, a semiconductor wafer 500 including semiconductor devices may be positioned under the cantilever probe needles 10.

Referring to step 830 and FIG. 7, the cantilever probe needles 10 are disposed on test pads 580 on the semiconductor wafer 500.

Referring to step 840 and FIG. 7, data representing electrical characteristics of the semiconductor devices may be generated.

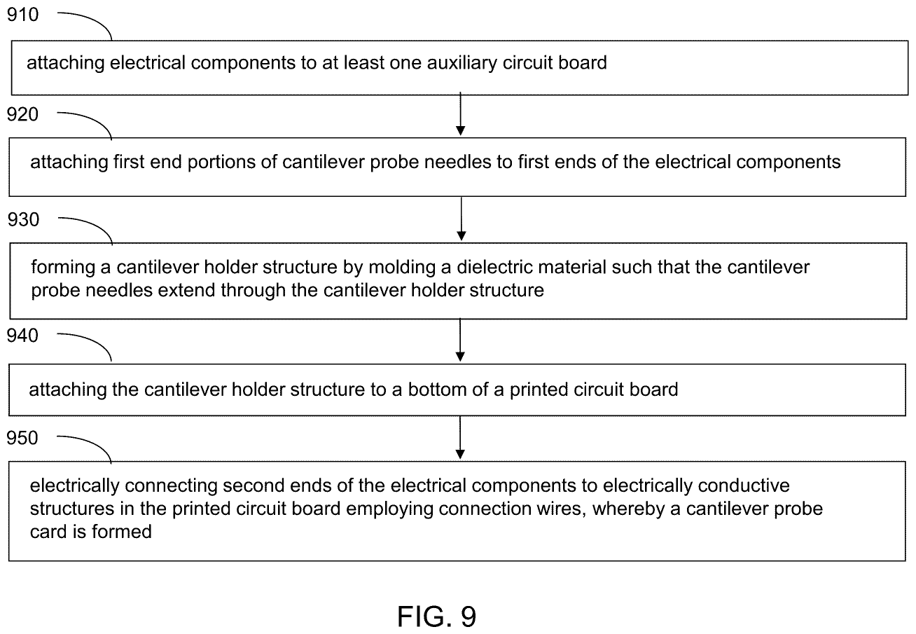

Referring to FIG. 9, a second flowchart illustrates the general processing steps for manufacturing a test apparatus according to an aspect of the present disclosure.

Referring to step 910 and FIG. 2A-5, electrical components 80 may be attached to at least one auxiliary circuit board 60.

Referring to step 920 and FIG. 2A-5, first end portions of cantilever probe needles 10 may be attached to first ends of the electrical components 80.

Referring to step 930 and FIG. 2A-5, a cantilever holder structure 460 may be formed by molding a dielectric material such that the cantilever probe needles 10 extend through the cantilever holder structure 460.

Referring to step 940 and FIG. 2A-5, the cantilever holder structure 460 may be attached to a bottom of a probe card 300.

Referring to step 950 and FIG. 2A-5, second ends of the electrical components 80 may be electrically connected to electrically conductive structures (312, 380) in the probe card 300 using connection wires 20, whereby a cantilever-card assembly 100 is formed.

Embodiments of the present disclosure provides enhanced signal integrity (SI) through shorter electrical paths that reduce noise and signal loss, and enhanced power integrity (PI) through placement of components closer to a device under test. By reducing signal decoupling and enhancing power stability, the limitations of traditional probe cards may be overcome, and higher test speeds may be obtained. Signal interference may be reduced to provide reliable signal transmission at high frequencies.

According to an aspect of the present disclosure, at least one auxiliary circuit board 60 may be used to mount electrical components 80 closer to contact points between cantilever probe needles 10 and the device under test. Flexible printed circuits (FPCs) or satellite printed circuit boards may be used as the at least one auxiliary circuit board 60. The length of the cantilever probe needles 10 may be shortened, which reduces signal degradation and noise coupling. The shortened length of the cantilever probe needles 10 improves signal and power integrity for high-speed loopback routings. The cantilever-card assembly 100 of the present disclosure provide enhanced testing efficiency and accuracy by improving signal and power integrity in the cantilever-card assembly 100.

Embodiments of the present disclosure provide a cantilever-card assembly 100 that incorporates at least one auxiliary circuit board 60, configured as a flexible printed circuit (FPC) or a satellite circuit board, to improve signal integrity and power integrity. The at least one auxiliary circuit board 60 may comprise at least one flexible printed circuit constructed from copper layers and a substrate of polyimide (PI), polyester (PET), or polytetrafluoroethylene (PTFE), and/or may comprise at least one satellite printed circuit board formed of a multilayer organic material. The flexible printed circuit(s) and/or the satellite printed circuit board(s) is/are embedded in, and/or attached to, the cantilever holder structure 460. Electrical components 80, such as capacitors, resistors, or inductors, are soldered directly onto the at least one auxiliary circuit board 60. An adhesive layer 62 may be used to attach the satellite circuit board(s) to the cantilever holder structure 460.

By embedding or attaching the at least one auxiliary circuit board 60 within the cantilever holder structure 460, the length of the cantilever probe needles 10 is reduced, thereby shortening the length of high-speed loopback routings, for example, to a length less than 2 mm. The reduced length minimizes signal degradation and coupling noise while enhancing power stability. The connection wires 20 may be used as coaxial cables with ground shielding, may provide electrical connections between the at least one auxiliary circuit board 60 and the probe card 300. The reduced length of electrical transmission paths, combined with the placement of the electrical components 80 in closer proximity to the cantilever probe needles 10 and the semiconductor wafer 500, improves signal and power delivery for the cantilever-card assembly 100 during operation. The cantilever-card assembly 100 of the present disclosure provides high-speed testing and fine-pitch alignment of the cantilever probe needles 10 while maintaining the structural and functional requirements of the cantilever-card assembly 100.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, sub-stitutions, and alterations herein without departing from the spirit and scope of the present disclosure.

What is claimed is:

1. A method of operating a test apparatus, the method comprising:
providing a cantilever-card assembly that comprises a cantilever holder structure attached to a bottom of a probe card, cantilever probe needles having first end portions embedded within the cantilever holder structure, at least one auxiliary circuit board that is attached to the cantilever holder structure, and electrical components attached to the at least one auxiliary circuit board;
positioning a semiconductor wafer including semiconductor devices under the cantilever probe needles;
disposing the cantilever probe needles on test pads on the semiconductor wafer; and
generating data representing electrical characteristics of the semiconductor devices.

2. The method of claim 1, wherein the cantilever-card assembly is provided in a configuration in which each of the at least one auxiliary circuit board comprises a respective planar surface in direct contact with the cantilever holder structure.

3. The method of claim 1, wherein the cantilever-card assembly is provided in a configuration in which the at least one auxiliary circuit board is vertically spaced from the probe card by a dielectric spacer ring that overlies the cantilever holder structure.

4. The method of claim 3, wherein the at least one auxiliary circuit board is not in direct contact with the probe card.

5. The method of claim 1, wherein the cantilever-card assembly is provided in a configuration in which:
the cantilever-card assembly comprises solder material portions attached to the electrical components; and
a subset of the cantilever probe needles is bonded to a first subset of the solder material portions.

6. The method of claim 5, wherein the cantilever-card assembly comprises connection wires that are solder-bonded to a second subset of the solder material portions and electrically connected to traces on the probe card.

7. The method of claim 1, wherein the at least one auxiliary circuit board comprises a flexible printed circuit comprising a dielectric substrate having a lower Young's modulus than a substrate material of the probe card and having a lesser thickness than the probe card.

8. The method of claim 1, wherein the at least one auxiliary circuit board comprises a satellite printed circuit board that is attached to the cantilever holder structure through an adhesive layer and vertically spaced from the probe card.

9. The method of claim 1, wherein:
the at least one auxiliary circuit board is in direct contact with a dielectric molding material of the cantilever holder structure; and
the first end portions of the cantilever probe needles extend through the cantilever holder structure.

10. The method of claim 1, wherein the cantilever-card assembly comprises additional cantilever probe needles having a respective first end that is attached to the probe card, having a respective center portion passing through the cantilever holder structure, having a respective second end portion extending downward from the cantilever holder structure.

11. A test apparatus comprising a cantilever-card assembly, the cantilever-card assembly comprising:
a probe card;
a cantilever holder structure attached to a bottom of the probe card;
cantilever probe needles having first end portions embedded within the cantilever holder structure and having second end portions vertically extending downward;
at least one auxiliary circuit board that is attached to the cantilever holder structure; and
electrical components attached to the at least one auxiliary circuit board.

12. The test apparatus of claim 11, wherein the at least one auxiliary circuit board is vertically spaced from the probe card by a dielectric spacer ring that overlies the cantilever holder structure.

13. The test apparatus of claim 11, wherein:
the cantilever-card assembly comprises solder material portions attached to the electrical components; and
a subset of the cantilever probe needles is bonded to a first subset of the solder material portions.

14. The test apparatus of claim 11, wherein the at least one auxiliary circuit board comprises a flexible printed circuit comprising a dielectric substrate having a lower Young's modulus than a substrate material of the probe card and having a lesser thickness than the probe card.

15. The test apparatus of claim 11, wherein the at least one auxiliary circuit board comprises a satellite printed circuit board that is attached to the cantilever holder structure through an adhesive layer and vertically spaced from the probe card.

16. A method manufacturing a test apparatus, comprising:
attaching electrical components to at least one auxiliary circuit board;
attaching first end portions of cantilever probe needles to first ends of the electrical components;
forming a cantilever holder structure by molding a dielectric material such that cantilever probe needles extend through the cantilever holder structure;
attaching the cantilever holder structure to a bottom of a probe card; and
electrically connecting second ends of the electrical components to electrically conductive structures in the probe card using connection wires, whereby a cantilever-card assembly is formed.

17. The method of claim 16, wherein the dielectric material of the cantilever holder structure is molded such that each of the at least one auxiliary circuit board comprises a respective planar surface in direct contact with the cantilever holder structure.

18. The method of claim 16, further comprising interposing a dielectric spacer ring between the cantilever holder structure and the probe card while attaching the cantilever holder structure to the probe card, wherein the at least one auxiliary circuit board is vertically spaced from the probe card by the dielectric spacer ring.

19. The method of claim 16, wherein:
the first end portions of cantilever probe needles are attached to the first ends of the electrical components using first solder material portions; and
the connection wires are attached to the second ends of the electrical components using second solder material portions.

20. The method of claim 16, further comprising:
providing additional cantilever probe needles, wherein the dielectric material is molded such that middle portions of the additional cantilever probe needles extend through the cantilever holder structure; and
soldering first end portions of the additional cantilever probe needles to conductive structures located directly on the probe card.
